(19) United States
(12) Patent Application Publication
(10) Pub. No.: US 2008/0238516 A1
(43) Pub. Date: Oct. 2, 2008

(54) Timing interpolator with improved linearity

(75) Inventor: Cosmin Iorga, Newbury Park, CA (US)

Correspondence Address: TERADYNE, INC.;c/o WOLF, GREENFIELD & SACKS, P.C., 600 ATLANTIC AVENUE, BOSTON, MA, 02210-2206, US

(73) Assignee: Teradyne, Inc., North Reading, MA (US)

(21) Appl. No.: 11/731,339

(22) Filed: Mar. 30, 2007

(51) Int. Cl. H03H 11/26

(52) U.S. Cl. 327/287; 327/285; 327/288

(57) ABSTRACT

A programmable timing interpolator circuit includes low output impedance buffer circuitry driving a node having a capacitance that varies in response to a programmed delay to be introduced by the interpolator. The low output impedance buffer circuitry receives a subset of course delay signals and, after buffering, provides the buffered course delay signals to fine delay circuitry. The buffer may include two source follower stages coupled to each other. The first source follower stage shifts the level of the received signal down. The second source follower stage shifts the level of the signal from the first source follower stage up. The first and second source follower stages are implemented using NMOS and PMOS technology.

### BACKGROUND OF INVENTION

1. Field of Invention

This application relates generally to automatic test equipment and more specifically to timing interpolator circuits.

2. Discussion of Related Art

During their manufacture, most semiconductor devices are tested at least once using some form of automated test equipment (generally, a “tester”). Modern semiconductor chips have numerous input/output points (I/O's) and, to fully test the semiconductor device, the tester must generate and measure signals for all of these I/O's simultaneously.

Modern testers generally have a “per-pin” architecture. A “pin” is circuitry within the tester that generates or measures one digital signal for the device under test (DUT). A “pin” is sometimes also called a “channel.” In a per-pin architecture, each channel can be separately controlled to generate or measure a different signal. As a result, there are many channels inside one tester. The channels are controlled by a pattern generator, which may be centralized or distributed over multiple circuits throughout the tester. The pattern generator sends commands to each channel to program it to generate or measure one test signal for each period of tester operation.

Each channel generally contains several edge generators, a driver/comparator and some format circuitry. Each edge generator is programmed to generate an edge signal (or more simply an “edge”) at a certain time relative to the start of each period. The format circuitry receives digital commands from the pattern generator indicating what signal should be generated or measured during a period. Based on this information, the formatter combines the edges into on and off commands for the driver/comparator. In this way, the driver and comparator measures or generates the correct valued signal at the correct time.

Each edge generator is in turn made up of two basic pieces: a counter and a interpolator, each of which is programmable. The counter is clocked by a relatively low-frequency first clock. It is programmed to count some number of periods of the first clock. It is triggered to start counting at the start of a tester period. In general, the period of the first clock will be smaller than the tester period so that the timing of edges within a tester period can be controlled fairly accurately simply by counting periods of the first clock. However, if the time of the edge is determined solely by counting the first clock, the resolution with which the edge can be generated is the same as the period of the first clock. For testing many semiconductor components, this resolution is not fine enough. The interpolator is used to provide finer time resolution.

The interpolator delays the output of the counter by a programmable amount that is smaller than one period of the first clock. For example, if the first clock has a period T, the interpolator may be programmed to generate an edge at any of X discrete intervals within the period T, where X depends on the resolution of the interpolator. Thus, the resolution with which timing edges can be generated is limited by the resolution of the interpolator, rather than the period of the first clock.

However, prior interpolators have suffered from a non-linear, or variable, error. In other words, if in theory the interpolator is programmable to generate an edge at any of X discrete intervals within the period T of the first clock, in practice the edge may occur slightly before or slightly after the desired interval, and the extent to which the edge occurs too early or too late may depend on which interval is chosen. In this way, the error in the timing of the edge is non-linear because the amount of error at each interval cannot be fit by a straight line. It is difficult to compensate for the non-linear error by calibration or other methods.

### SUMMARY OF INVENTION

Improved linearity is provided in a timing interpolator. In embodiments of the invention, the timing interpolator circuit comprises a low output impedance buffer for buffering a signal from a coarse delay stage. The buffered signal is sent to interpolator input stage circuitry, which provides a fine delay of the coarse delay signal. In embodiments, the timing interpolator circuit is implemented in low voltage CMOS technology.

Aspects of the present invention provide a timing interpolator circuit comprising a buffer having an input and an output with a source follower stage. The timing interpolator circuit further comprises input stage circuitry having an input connected to the output of the buffer. The timing interpolator circuit further comprises a variable current source coupled to the input stage circuitry.

According to other aspects of the invention, a timing circuit is provided comprising coarse delay circuitry configured to receive a clock signal and comprising a plurality of coarse delay stages configured to output a plurality of coarse delay signals of the clock signal. The timing circuit further comprises a multiplexer configured to receive the plurality of coarse delay signals and to output a subset of the plurality of coarse delay signals. The timing circuit further comprises fine delay circuitry configured to provide a fine delay of the subset of coarse delay signals, the fine delay circuitry comprising a control input and a programmable current source, the programmable current source adapted to provide a current at a level that varies in response to a value at the control input. The timing circuit further comprises a buffer configured to receive the subset of coarse delay signals and to output buffered signals to the fine delay circuitry.

According to other aspects of the invention, a method of operating a timing generator having a coarse delay stage and a fine delay stage is provided. The method comprises programming a current source in the fine delay stage, and generating a signal in the coarse delay stage. The method further comprises buffering the signal in a first stage, the buffering in the first stage shifting the voltage of the signal in a first direction. The method further comprises buffering the signal in a second stage, the buffering in the second stage shifting the voltage of the signal in a second direction, opposite the first direction. The method further comprises applying the signal buffered in the second stage to an input of the fine delay stage.

### BRIEF DESCRIPTION OF DRAWINGS

The invention will be better understood by reference to the following more detailed description and accompanying drawings in which:

FIG. 1 is a sketch illustrating the architecture of a semiconductor tester;

FIG. 2 is a simplified schematic of one timing edge generator in a test system;

FIG. 3 is a simplified schematic of a prior art timing interpolator;

FIG. 4 is a more detailed schematic of the prior art timing interpolator circuit of FIG. 3;

FIG. 5 is a simplified schematic of a timing interpolator circuit according to the present invention;

FIG. 6 is a more detailed schematic of a portion of the timing interpolator circuit of FIG. 5.

The accompanying drawings are not intended to be drawn to scale. In the drawings, each identical or nearly identical component that is illustrated in various figures is represented by a like numeral.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

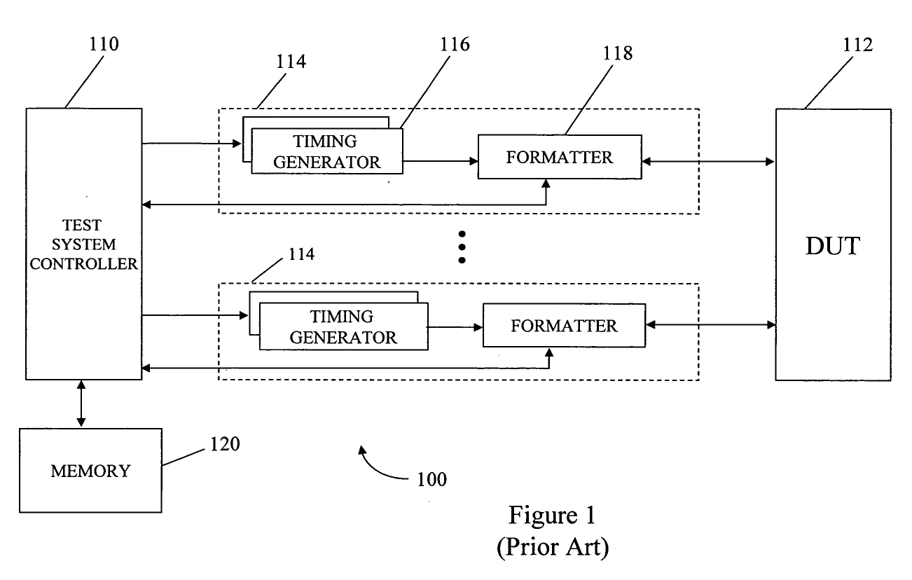

The present invention may be applied in testers like those previously described in the Background section, as well as in other settings. For example, FIG. 1 shows one example of a prior art tester to which the present invention may apply. It will be recognized by one of skill in the art that the present invention is not limited to testers having the configuration shown in FIG. 1. FIG. 1 shows a tester 100 in simplified block diagram form. Tester 100 is controlled by a test system controller 110. Test system controller 110 generates digital control values for each channel 114 of tester 100. The digital control values specify such things as timing data, i.e., when each channel should generate or measure a test signal, the value that should be generated and the format for that test signal.

Control information is provided for each cycle during which the tester operates. The data needed to specify what signals each channel should be generating or measuring for every cycle during a test is sometimes called a pattern. The pattern is stored in memory 120.

In addition to providing digital control values, test system controller 110 provides a signal that identifies the start of each tester cycle. This signal, as well as the digital control values, are provided to a plurality of channels 114. A typical tester may have hundreds or thousands of channels, however the number of channels is not critical to the invention. Each channel generally contains the same circuitry, though some testers may have different types of channels to support generation and measurement of a range of signals that differ in frequency or other characteristics.

Within each channel 114 are a plurality of timing generators 116. Each timing generator 116 generates a timing edge that controls the time of an event within tester 100. The events may be such things as the start of a test pulse applied to a device under test 112 or the end of the test pulse. An edge may also be used to trigger measurement of a signal from device under test (DUT) 112.

The time at which a timing edge should occur is specified relative to the start of the tester cycle. The timing data therefore indicates the amount of delay after the start of the cycle when the timing edge is to be generated. The timing information may be specified by several groups of data bits, each group of bits representing time periods of finer and finer resolution. The most significant group of bits may represent delay as an integer number of periods of a first clock. The amount of delay specified by the most significant group of bits can be easily generated by counting an integer number of pulses of the first clock. The next most significant group of bits may represent delay in intervals that are some fraction of the first clock. These bits are sometimes called the “fractional portion” of the timing data. This delay must be generated by an interpolator. For example, an interpolator according to aspects of the present invention could be used to provide the desired delay.

The timing edges from all of the timing generators 116 within a single channel are passed to a formatter 118. In addition to receiving timing edges, formatter 118 also receives other control information from test system controller 110. This control information may indicate the value of the test signal to be generated during a period, i.e. a logical 1 or a logical 0. It may specify other things such as the format of the signal applied to device under test 112. For example, formats such as “return to zero,” “surround by complement,” “return to one,” and “non-return to zero” are all sometimes used. These formats may be imposed by formatter 118.

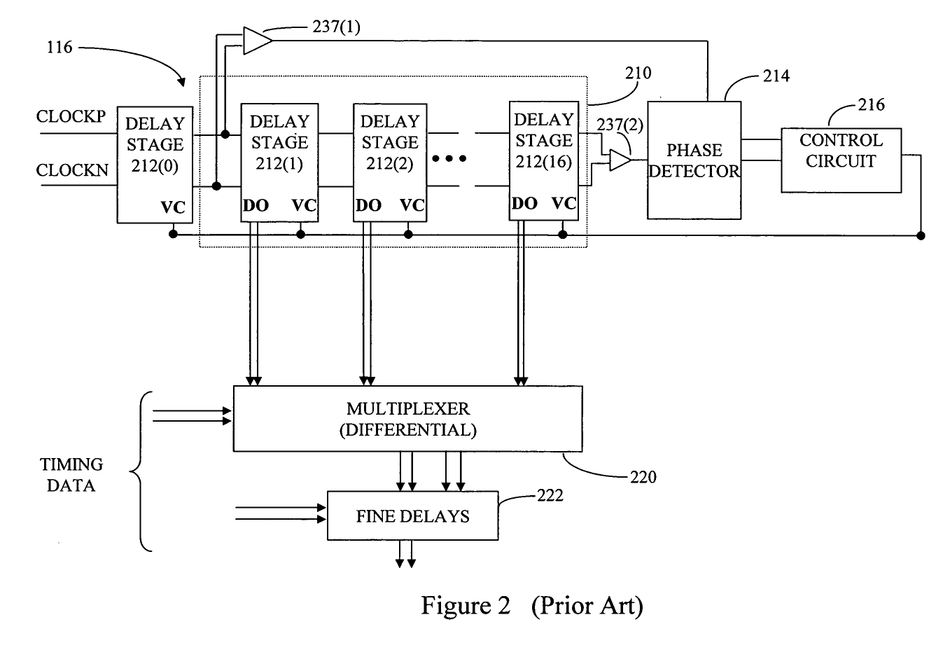

Turning now to FIG. 2, an example of the circuitry of a timing generator 116 is shown. Digital timing data from test system controller 110 is applied to timing generator 116. Timing generator 116 then produces a timing edge that is used by formatter 118 (FIG. 1) or elsewhere in the tester.

A digital delay line 210 is shown. The delay line may be a CMOS delay line and may be a differential delay line. FIG. 2 shows that 16 delay stages 212(1) . . . 212(16) are cascaded in delay line 210. The input to delay line 210 is derived from a first clock, which is shown as a differential clock on lines CLOCKP and CLOCKN. Before application to delay line 210, the first clock is conditioned in delay stage 212(0). More than one delay stage could be used for conditioning. Delay stage 212(0) is like the other stages in delay line 210. In this way, the input of every delay stage 212(1) . . . 212(16) in delay line 210 receives an input signal from the same kind of circuitry. All of the delay stages 212(1) . . . 212(16) therefore receive inputs with the same voltage swing, which leads to less variation in delay from stage to stage.

The first clock has a frequency of approximately 1-2 GHz. However, the frequency of the first clock is not critical to the invention and could even be variable. The first clock may be a highly stable clock that is routed to all timing generators 116 in tester 100, though any suitable clock may be used.

The input and output of delay line 210 are fed to phase detector 214 through differential to single ended buffer amplifiers 237(1) and 237(2), respectively. The output of phase detector 214 is fed to control circuit 216. Control circuit 216 produces a control signal that is fed back to a control input, VC, in each delay stage 212. The control signal adjusts the delay through each delay stage 212. Delay line 210, phase detector 214 and control circuit 216 implement what is known as a Delay Locked Loop. The loop is said to be “locked” when the delay through delay line 210 equals one period of the first clock. In the embodiment of FIG. 2, when the loop is locked, each delay stage delays the first clock by one sixteenth of a period of the first clock.

Phase detector 214 is as conventionally found in a delay locked loop. Control circuit 216 is similar to a charge pump as used in a conventional delay locked loop. However, it may be modified to reduce the cross talk between interpolators, if multiple interpolators are provided.

The output DO of each delay stage 212 is fed to a differential multiplexer 220. Multiplexer 220 can be controlled to select the output of two adjacent delay stages 212 as specified by certain bits of the timing data. Because the outputs of delay stages 212 are delayed by one sixteenth of the period of the first clock, the output of multiplexer 220 provides clock signals that have been delayed by a multiple of one sixteenth of the first clock period.

To get finer resolution on the delay, the outputs of multiplexer 220 are passed to a fine delay circuit 222. As will be discussed in further detail below, the fine delay circuit 222 may be an interpolator, for example an interpolator according to aspects of the present invention. Fine delay circuit 222 is controlled by the timing data. Depending on the number of bits used to control fine delay circuit 222, additional delay that is some multiple of a fraction of the first clock is obtained. For example, if 4 bits are used to control the fine delay circuit, these bits represent an additional delay that is a multiple of 1/256 of a period of the first clock.

The output of fine delay 222 is a differential signal representing a delayed version of the first clock. It is delayed by a fraction of a period of the first clock. In FIG. 2, the delay is some multiple of 1/256 of the first clock period. The differential signal may be applied to further circuitry (not shown) within the tester and act as a timing edge that causes the circuitry to take a programmed action at the appropriate time.

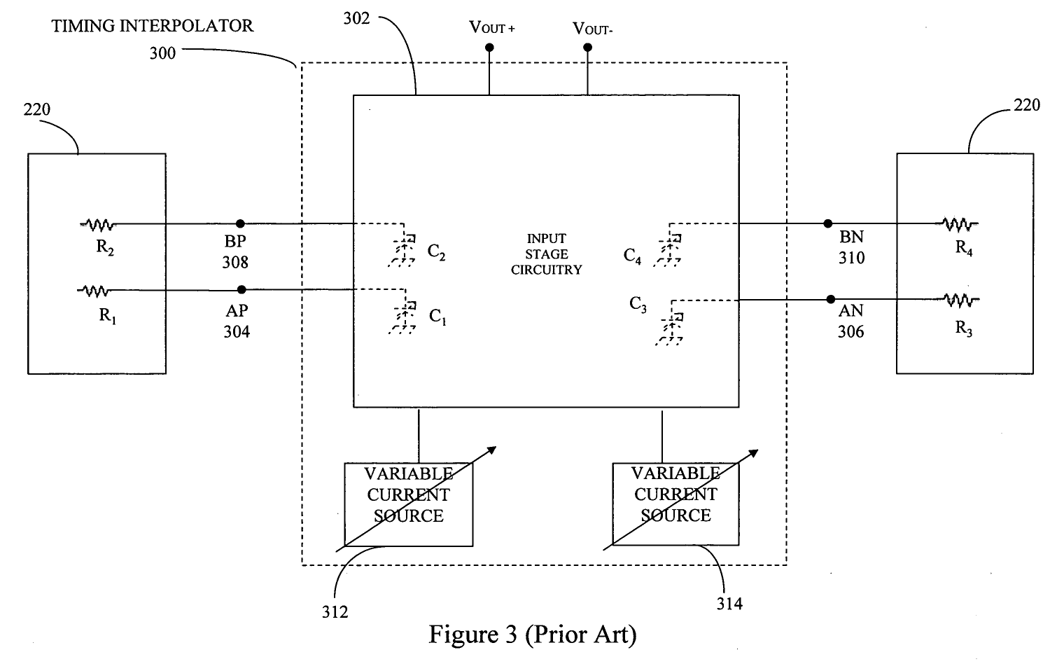

FIG. 3 is a simplified schematic of a conventional timing interpolator 300. For example, the timing interpolator 300 could correspond to the fine delay circuit 222 in FIG. 2. The timing interpolator 300 includes input stage circuitry 302. The input stage circuitry 302 is configured to receive two differential input signals. For example, the differential input signals can be received from multiplexer 220 in FIG. 2, representing outputs of two adjacent stages in delay line 210. The first differential input signal A may be applied across positive input AP 304 and negative input AN 306. The second differential input signal B may be applied across positive input BP 308 and negative input BN 310.

d variable capacitance associated variable capacitance. The input stage circuitry 302 is coupled to variable current source 312 and variable current source 314, which will be described in further detail below. The timing interpolator 300 provides a differential output signal across a positive output Vout+ and a negative output Vout−. As mentioned in connection with FIG. 2, the differential output signal may act as a timing edge to cause further circuitry within the tester to perform a programmed function at the appropriate time.

In operation, the input stage circuitry receives signals from the multiplexer 220 as previously described. Specifically, differential signals A and B correspond to signals output from two adjacent delay stages 212 of FIG. 2 that are selected by the multiplexer 220. Switching of the differential output signal is dictated by a weighted combination of the differential input signals A and B. The weighting of the differential input signals is dictated by the relative proportion of the current through input stage 302 supplied by each of the variable current sources 312 and 314. When all of the current is supplied by variable current source 312 the output of input stage 302 switches at a time defined by switching of the input signal A applied across inputs AP 304 and AN 306. Conversely, when all of the current is supplied by variable current source 314, the output switches at a time defined by switching of input signal B applied across inputs BP 308 and BN 310. when the current is supplied by both variable current sources 312 and 314 the output switches at a time between the switching of signals A and B, with that time occurring at a point in the interval between the switching of A and B that is proportional to the proportion of the total current supplied by variable source 314.

In the embodiment illustrated, the variable current sources 312 and 314 are programmable, which allows controlled selection of the weighting of the differential input signals A and B. As a result, the delay introduced by interpolator 300 may be programmed by changing the amount of current through each current source 312 and 314.

As previously described, the differential input signals, corresponding to differential outputs of the delay stages 212, are delayed from the start of the first clock by some multiple of 1/16 of the period of the first clock because there are 16 delay stages 212. The timing interpolator 300 enables tuning of the output signal Vout within some smaller fraction of the period of the first clock, and more specifically between the edge of input signal A and the edge of input signal B. The specific construction of the variable current sources 312 and 314 will dictate how finely the tuning can be done.

While controlling signal timing by changing current flow may be desirable, we have appreciated that it may also lead to timing errors, as described in more detail below.

Each input of the input stage circuitry has an inherent input capacitance (shown in dotted lines). For example, input AP 304 has an associated variable capacitance C₁. Input BP 308 has an associated capacitance C₂. Input AN 306 has an associated capacitance C₃. Input BN 310 has an associated capacitance C₄. In addition, the outputs of the circuitry providing signals A and B, shown in this example as the multiplexer 220 of FIG. 2, have associated output impedances on each output line, shown as R₁, R₂, R₃, and R₄. The combination of the output impedance of an upstream stage, such as multiplexer 220 with the input capacitance creates an RC time constant that creates a delay between application of signals A and B to timing interpolator 300 and when timing interpolator 300 reacts, that represents a timing error. We have appreciated that this timing error depends on the current flow through each current source 312 and 314 because the input capacitances C₁, C₂, C₃ and C₄ depend on current. Because the current changes to program the amount of intended delay introduced by timing interpolator 300, the timing error also changes as the programmed value changes. We have appreciated that the change in timing error changes non-linearly, creating a non-linear error that is difficult to correct through calibration. However, as described in more detail below, the amount of the nonlinear timing error can be reduced by an improved circuit configuration.

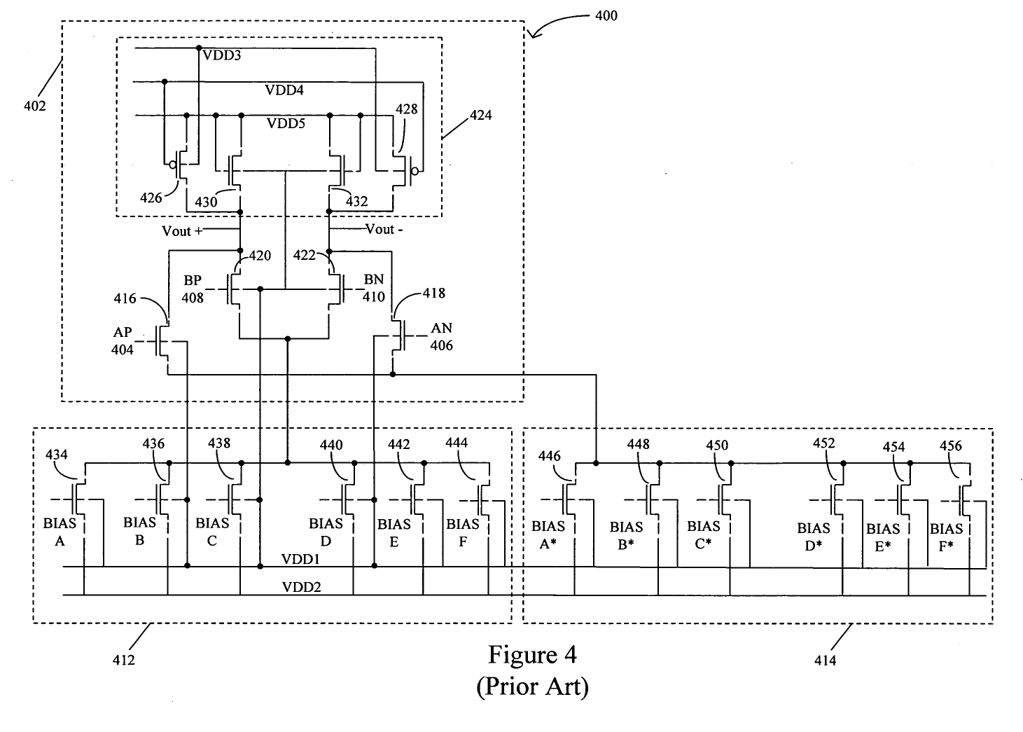

FIG. 4 is a schematic of an implementation of the timing interpolator circuit of FIG. 3. The timing interpolator 400 includes input stage circuitry 402. The input stage circuitry 402 is configured to receive two differential input signals. The first differential input signal A is applied across a positive input AP 404 and a negative input AN 406. The second differential input signal B is applied across a positive input BP 408 and a negative input BN 410. The input stage circuitry is coupled to variable current source 412 and variable current source 414. The timing interpolator 400 provides a differential output signal across a positive output Vout+ and a negative output Vout−.

As shown in FIG. 4, the input stage circuitry configured to receive the differential input A includes a differential pair of transistors comprising two NMOS transistors 416 and 418. The gates of transistors 416 and 418 receive input signals AP 404 and AN 406, respectively. The source terminals of transistors 416 and 418 are connected to each other and to variable current source 414. The substrates of transistors 416 and 418 are biased by a signal VDD1. Similarly, the input stage circuitry configured to receive the differential input B includes a differential pair of transistors comprising two NMOS transistors 420 and 422. The gates of transistors 420 and 422 receive input signals BP 408 and BN 410, respectively. The source terminals of transistors 420 and 422 are coupled to each other and to variable current source 412. The substrates of transistors 420 and 422 are biased by signal VDD1. The input stage circuitry 402 also includes a conventional load block 424 consisting of four transistors 426, 428, 430, and 432. Transistors 426 and 428 are PMOS transistors. Transistors 430 and 432 are NMOS transistors. The drain terminal of transistor 426, and the source terminal of transistor 430 are connected to the drain terminals of transistors 416 and 420. The output signal Vout+ is taken from this common point. Similarly, the drain terminal of transistor 428 and the source terminal of transistors 432 are connected to the drain terminals of transistors 418 and 422. The output signal Vout− is taken from this common point.

Signal VDD3 biases the substrates of PMOS transistors 426 and 428. Signal VDD4 is applied to the gate terminals of PMOS transistors 426 and 428. The substrates of NMOS transistors 430 and 432 are biased by signal VDD1. Signal VDD5 is applied to the gate terminals of transistors 430 and 432. Signal VDD4 is applied to the gate terminals of transistors 426 and 428. Signal VDD5 is applied to the source terminals of transistors 426 and 428, and the drain terminals of transistors 430 and 432.

The source terminals of the NMOS transistors 420 and 422 are connected to the variable current source 412. The variable current source 412 comprises six NMOS transistors, 434, 436, 438, 440, 442, and 444. The transistors of the variable current source 412 may all be the same size or may have sizes that provide a binary weighted current flow. The drain terminals of all six transistors are connected to the source terminals of transistors 420 and 422. The source terminal of each of the six NMOS transistors of variable current source 412 is connected to signal VDD2. Each gate of the six transistors receives a respective bias signal, BIAS A, . . . , BIAS F that acts as a control input. In this manner, the variable current source 412 is programmable. The substrates of all six transistors are biased by signal VDD1.

The source terminals of the NMOS transistors 416 and 418 are connected to the variable current source 414. The variable current source 414 comprises six NMOS transistors, 446, 448, 450, 452, 454, and 456. The transistors of the variable current source 414 may all be the same size or may have sizes that provide a binary weighted current flow. The drain terminals of all six transistors are connected to the source terminals of transistors 416 and 418. The source terminal of each of the six NMOS transistors of variable current source 414 is connected to signal VDD2. The substrates of all six transistors are biased by signal VDD1.

Each gate of the six transistors receives a respective bias signal which is the logical opposite of the bias signal for a corresponding transistor in variable current source 412. For example, the gate of transistor 446 receives signal BIAS A*. The gate of transistor 448 receives signal BIAS B*. Therefore, if transistor 434 is on, then transistor 446 is off. If transistor 436 is on, then transistor 448 is off, and so on for the other transistors in variable current sources 412 and 414. In this manner, as with variable current source 412, the variable current source 414 is programmable to adjust the proportion of total current through input stage circuitry 402 provided by each current source 412 and 414. Because the gates of the transistors in variable current source 412 receive a logical opposite signal to the gates of the corresponding transistors in variable current source 414, the variable current sources in combination allow 6-bit programming capability. However, it will be recognized that the number of transistors in the variable current sources 412 and 414 is not critical to the invention and does not limit the invention in any way.

The timing interpolator of FIG. 4 provides a fine delay output of the course delay signal described in relation to FIG. 2. As mentioned, the differential input signals A and B correspond to signals output from adjacent delay stages 212 in FIG. 2 that have been selected by multiplexer 220. Therefore, in the embodiment of FIG. 2, because there are 16 delay stages, the input signal A may have a signal transition, for example, at time xₒ, while the input signal B may have a transition at time xₒ+( 1/16)T, where T is the period of the first clock signal. Timing interpolator 400 provides finer resolution within the time between when input signal A and when input signal B transitions. The resolution is determined by the resolution of variable current sources 412 and 414. In the architecture of FIG. 4, the variable current sources 412 and 414 provide 6-bit resolution. In other words, the timing interpolator can divide the time between when input signal A transitions and when input signal B transitions into 2⁶, or 64, intervals, thus increasing resolution by a factor of 64.

As mentioned with regard to FIG. 3, the output signal transitions at a time that is a weighted combination of the transition times of differential input signals A and B. The weighting is dictated by the variable current sources 412 and 414, so that the output Vout can transition on any of the 64 intervals between when differential input signal A transitions and when differential input signal B transitions. For example, if the transistors of variable current source 414 are all on, then the transistors of variable current source 412 are all off. In this scenario, the output signal Vout is dictated solely by the differential input signal A, and will transition when differential input signal A transitions. Likewise, if the transistors of variable current source 412 are all on, then the transistors of variable current source 414 are all off. In this scenario, the output signal Vout is dictated solely by the differential input signal B, and will transition when differential input signal B transitions. For any other combination of ON and OFF states of the transistors of variable current sources 412 and 414, the output signal Vout will transition at a time dictated by a weighted combination of the transition times of the differential input signals A and B, dictated by which of the transistors 434, 436, 438, 440, 442, 444, 446, 448, 450, 452, 454 and 456 are on. Accordingly, the timing interpolator 400 can produce an output signal Vout having an edge at any of the 64 intervals by proper activation of the transistors in the variable current sources 412 and 414.

The practical operation of timing interpolator 400 involves an error, as previously mentioned. Specifically, while in theory the edge of output signal Vout can be chosen at any of the discrete intervals provided by the 6-bit resolution of the variable current sources, in practice the edge of the output Vout sometimes occurs earlier or later than the desired interval, creating a timing error. Moreover, this error can be nonlinear. Applicant has appreciated that the described error in the operation of timing interpolator 400 can be understood by consideration of the structure shown in FIG. 3. As illustrated in FIG. 3, the multiplexer has an output impedance corresponding to each output line, represented as R1, R2, R3, and R4. This output impedance combines with the respective variable input capacitances C1, C2, C3, and C4 to form an RC time constant causing a timing error.

Applicant has appreciated that the variable input capacitance of the input stage circuitry of the timing interpolator 400 varies with the drain current of the transistors 416, 418, 420, and 422. Because the drain current of these transistors varies with the digital select code, i.e., which transistors of the variable current sources 412 and 414 are on or off, the capacitance varies in relation to the digital select code.

If the output impedances R1, R2, R3, or R4 of the multiplexer 220 are large, the resulting change in the RC time constant may be sufficiently large to create an appreciable change in the timing error that is difficult to correct by traditional calibration techniques.

Applicant has appreciated that the variable nature of the error can remedied by providing circuitry between the multiplexer and the input stage circuitry of the timing interpolator having a low output impedance. If the output impedance of this circuitry is sufficiently low, then the change in the RC time constant created by changes in the variable capacitances [C₁, C₂, C₃ and C₄] will be sufficiently small as to not effect the desired operation of the timing interpolator.

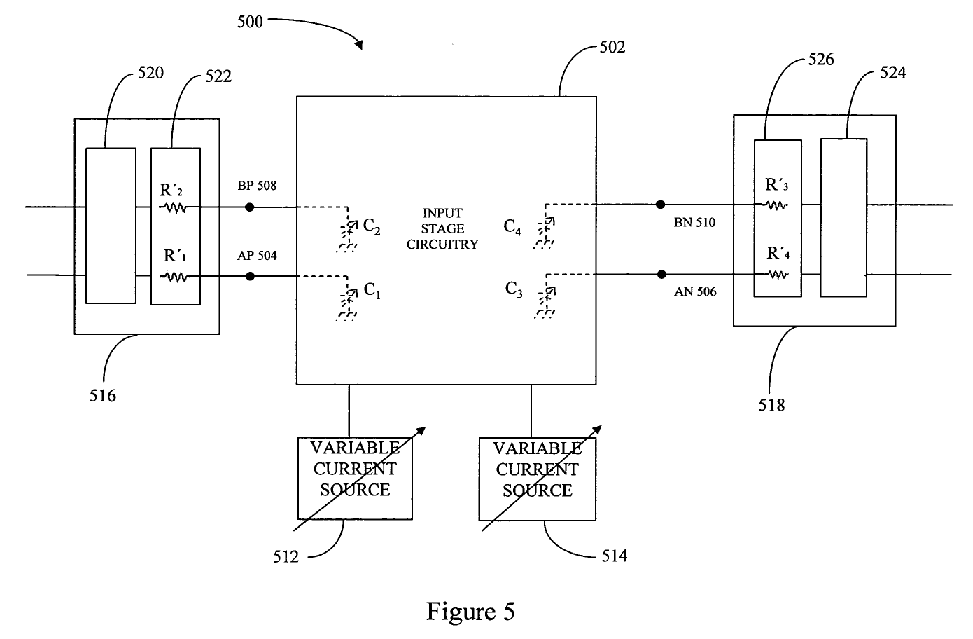

FIG. 5 shows a simplified schematic of a timing interpolator circuit according to the present invention. The timing interpolator circuit 500 comprises input stage circuitry 502, which may be equivalent to that shown previously in FIGS. 3 and 4. The timing interpolator circuit further comprises variable current sources 512 and 514, which also may be equivalent to those shown in FIGS. 3 and 4. The timing interpolator circuit further comprises buffer 516 and buffer 518. The buffers 516 and 518 have output impedances R′₁, R′₂, R′₃ and R′₄, which may be lower than R₁, R₂, R₃ and R₄ respectively, of the upstream circuitry illustrated in FIG. 3. In one embodiment, the buffer 516 comprises a first source follower stage 520 and a second source follower stage 522. Similarly, buffer 518 comprises a first source follower stage 524 and a second source follower stage 526. However, one of skill in the art will recognize that other configurations of buffers 516 and 518 are possible.

In addition, the configuration of the timing interpolator circuit may impose further constraints on the configuration of buffers 516 and 518. For example, if the timing interpolator is implemented in low voltage CMOS technology, the power supply margin may impose a restriction on how the buffers 516 and 518 can be implemented.

In the illustrated embodiment, the buffers 516 and 518 receive differential input signals from a multiplexer (not shown), such as the multiplexer 220 shown in FIG. 3. One leg of each of the differential signals is input to source follower stage 520, while the other leg of each of the differential signals is input to source follower stage 524. Source follower stages 520 and 524 may be identical to each other in construction and operation, as will be described in further detail below. Though each source follower stage has a low output impedance, approximately in the range of 10-50 ohms, each source follower stage 520, 524 may shift the level of the signal it receives down by some amount. The signals may be sent from the source follower stages 520 and 524 to the source follower stages 522 and 526, respectively. The source follower stages 522 and 526 may be identical to each other in construction and operation, as will be described in further detail below. Each source follower stage 522 and 526 operates to shift the level of the signal it receives up. The outputs of the source follower stages 522 and 526 are coupled to inputs AP 504, AN 506, BP 508, and BN 510. The operation of input stage circuitry 502 and the variable current sources 512 and 514 may be identical to the operation of the circuitry previously shown and described with respect to FIG. 4.

The level shifting operations of the source follower stages may be performed to preserve the level of signals input to the buffers 516 and 518. For example, in one embodiment the source follower stage 520 may decrease the level of a signal input to source follower stage 520 by an amount A. This decrease in the output level is analogous to a downward shift in the voltage level supplied to the inputs of input stage 502. As can be seen in FIG. 4, the inputs of input stage 502 are applied to the gates of transistors such as 404, 406, 408 and 410. The sources of these transistors are coupled to the drains of the transistors that form current sources 412 and 414. Accordingly, the drain voltages for those transistors 434, 436, 438, 440, 442, 444, 446, 448, 450, 452, 454 and 456 equal the source voltages of the input transistors to input stage 402. In proper operation, the source voltages of the input transistors and therefore the drain voltages of the transistors in current sources 412 and 414 will be lower than the input voltages at the gates of transistors 404, 406, 408 and 410 whenever those transistors are on. Consequently, reducing the maximum input level to input stage 402 reduces the gate voltage to those transistors when in the ON state, which in turn reduces the drain voltage of the transistors forming current sources 412 and 414.

For the current sources 412 and 414 to operate properly, the drain voltages of the transistors that form those current sources must be sufficiently large to ensure that the transistors operate in their saturation regions. For low voltage CMOS circuitry, voltage levels within the circuit are often designed such that the drain voltages on current sources, such as 412 and 414 is only slightly above the level needed to provide operation of the transistors in the current sources in saturation mode. Consequently, a downward level shift at the input stage 402 can lower the voltages at the drains of the transistors that form current sources 412 and 414, interfering with the intended operation of current sources 412 and 414.

In the embodiment illustrated, a second source follower stage is used in buffers 516 and 518 to adjust the output level of buffer amplifiers 516 and 518 to provide a level allowing proper operation of current sources 512 and 514. In the embodiment illustrated in FIG. 5, source follower stages 522 and 526 are included to provide a level shift upward. In the embodiment illustrated, the source follower stage 522 shifts the signal it receives from source follower stage 520 up by an amount to compensate for the shift down by the amount A in source follower stage 520.

Buffer 518 operates similarly to buffer 516. The amount A may be determined by the circuitry used to implement the source follower stages 520, 522, 524, and 526.

As mentioned, the buffers 516 and 518 are low output impedance buffers. As a result, the low output impedance of the buffers combines with the previously described variable input capacitances of the input stage circuitry to form an RC time constant that is relatively insensitive to changes in the input capacitance of input stage 502. As a result, the variable nature of the input capacitances of the input stage circuitry does not effect the overall operation of the timing interpolator circuit.

In one embodiment, the circuitry of FIG. 5, which is configured to provide a fine delay to a subset of coarse delay signals received from the multiplexer, comprises a control input and a programmable current source. The programmable current source may be adapted to provide a current at a level that varies in response to a value at the control input.

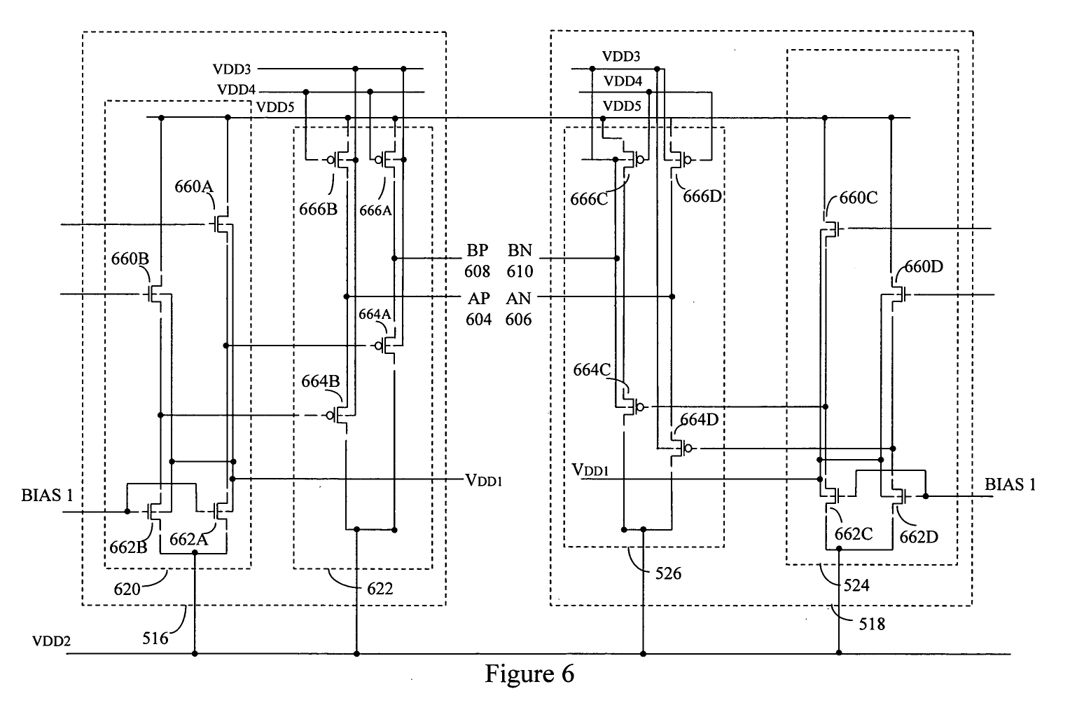

FIG. 6 is a detailed schematic of one possible configuration of the buffers 516 and 518 of FIG. 5 that provides a low output impedance and also is compatible with the power supply margin constraints of low voltage CMOS technology. As shown in FIG. 6, each of the legs of each of the differential signals input to input stage 502 may be processed similarly. In the embodiment illustrated, each leg is processed in a path that comprises two source followers. For simplicity, only the configuration and operation of one of the four paths will be described in detail.

The buffer 516 comprises first source follower stage 620 and second source follower stage 622. The first source follower stage 620 comprises a first NMOS source follower comprising transistor 660A. The gate terminal of transistor 660A receives one leg of a differential signal from upstream circuitry within the tester, for example a multiplexer like that shown in FIG. 3. In this example, transistor 660A receives a signal from the multiplexer that, after passing through the buffer 516, that is applied to input BP 608. Likewise, the gate of transistor 660B receives a signal from the multiplexer that, after passing through the buffer 516, is applied to input AP 604. The gate of transistor 660C of buffer 518 receives a signal from the multiplexer that, after passing through the buffer 518, is applied to BN 610. The gate of transistor 660D receives a signal from the multiplexer that, after passing through the buffer 518, is applied to input AN 606.

The drain terminal of transistor 660A receives a signal VDD5. The substrate of transistor 660A is biased by signal VDD1, also shown in FIG. 4. The source follower stage 620 further comprises NMOS transistor 662A, configured as a load for transistor 660A. The source terminal of transistor 660A is connected to the drain terminal of transistor 662A. The output of the first source follower stage is taken from this common point. The gate terminal of transistor 662A receives a bias signal BIAS 1. The source terminal of transistor 662A is connected to a source terminal of transistor 662B, both of which are connected to signal VDD2. The substrate of transistor 662A is biased by signal VDD1.

The second source follower stage 622 comprises a second PMOS source follower comprising PMOS transistor 664A. The gate terminal of transistor 664A is connected to the source terminal of transistor 660A of the first source follower stage 620, thus coupling the output of the first stage to the input of the second stage. Transistor 666A is configured as a load for transistor 664A. Specifically, the source terminal of transistor 664A is connected to the drain terminal of transistor 666A. The source terminal of transistor 666A is connected to signal VDD5. The gate terminal of transistor 666A is connected to signal VDD4. The substrates of both transistors 664A and 666A are biased by signal VDD3. The output of the second PMOS source follower is taken from the source of transistor 664A, and corresponds to input signal BP 608 fed to the input stage circuitry of the timing interpolator 500 of FIG. 5.

The operation of the buffers will be described with particularity by focusing on the operation of the “A” path of the buffer 516, i.e., the transistors 660A, 662A, 664A, and 666A. It will be recognized by one of skill in the art that the operation of the “B”, “C”, and “D” paths is identical. As used herein, the “B” path contains transistors 660B, 662B, 664B and 666B. Likewise the “C” path contains transistors 660C, 662C, 664C and 666C and the “D” path contains transistors 660D, 662D, 664D and 666D.

Transistor 660A receives at its gate terminal a signal corresponding to one leg of a differential output from the multiplexer of FIG. 3. The combination of transistors 660A and 662A acts as a source follower, providing an output signal at the source terminal of transistor 660A. The output signal is shifted down relative to the signal at the gate of transistor 660A by an amount A dependent on the characteristics of the transistors used in the source follower, as will be recognized by one of skill in the art. This output signal of the transistor 660A is then input to the second source follower stage 622, and specifically the gate terminal of PMOS transistor 664A. The combination of transistors 664A and 666A act as a second source follower, providing an output signal at the source terminal of transistor 664A. The output signal is shifted up relative to the signal at the gate of transistor 664A by an amount dependent on the characteristics of the transistors used in the source follower, as will be recognized by one of skill in the art. As a result, the signal at the source terminal of transistor 664A is shifted up relative to the signal at the drain of transistor 662A. The amount of the shift is dependent on the characteristics of the second source follower, and may be made to equal the amount A of the downward shift created by the first source follower stage 516. The output signal of source follower stage 622 therefore may have a level approximately equal to the signal input to the buffer 516 by the multiplexer or other level suitable for driving input stage circuitry 502 without lowering the drain voltage of transistors forming current sources 412 and 414 to the point that those transistors cease operation in saturation. However, the buffer 516 has a lower output impedance than the multiplexer. Therefore, the timing interpolator circuit does not suffer from a non-linear error in the timing of the output signal Vout.

The configuration described above is compatible with low voltage CMOS technology, and respects the power margin constraints of such technology. Though the specific voltage levels employed in the circuit are not a limitation on the invention, the circuit described in FIGS. 5 and 6 may operate with voltage differences between VDD5 and VSSA of approximately 1.3 Volts. With transistors such as transistors 434, 436, 438 . . . forming current sources requiring a drain to source voltage of approximately 0.3 Volts to operate in saturation mode, the circuit configurations described above provide an adequate operating margin. Consequently, the circuits described above contribute to high speed and accurate timing systems for semiconductor testers.

Having thus described several aspects of at least one embodiment of this invention, it is to be appreciated various alterations, modifications, and improvements will readily occur to those skilled in the art. One of skill in the art will recognize that various alternatives to the architecture of FIG. 5 and FIG. 6 are within the scope and spirit of the invention. For example, while the Figures illustrate two buffers, it will be recognized that because the four paths in FIG. 6 are identical, the configuration could be represented by a single buffer, four buffers, or any other appropriate number of buffers. The invention is not limited in this regard.

For example, the invention is not limited to testers that are controlled centrally. The invention may be applied to testers having configurations other than those described herein. Further, the invention may be applied in context other than semiconductor test systems. High speed and accurate timing may be desirable in test systems to test printed circuit boards or other components for assemblies. Further, the timing interpolator described above may be used in any system in which accurate time interpolation is desired. The invention is not limited to low voltage CMOS technology. The invention may be implemented in CMOS technology, regardless of the voltage levels at which the circuits operate. Further, the interpolator described above may be implemented with any suitable semiconductor technology.

Such alterations, modifications, and improvements are intended to be part of this disclosure, and are intended to be within the spirit and scope of the invention. Accordingly, the foregoing description and drawings are by way of example only.

What is claimed is:

1. A timing interpolator circuit, comprising:
a buffer having an input and an output and comprising a source follower stage; input stage circuitry having an input connected to the output of the buffer; and
a variable current source coupled to the input stage circuitry.

2. The timing interpolator circuit of claim 1, wherein the buffer further comprises a second source follower stage; and
wherein the source follower stage is configured to receive a signal input to the buffer and to output a signal to the second source follower stage.

3. The timing interpolator circuit of claim 2, wherein the second source follower stage of the buffer is configured to provide a signal to the input stage circuitry.

4. The timing interpolator circuit of claim 3, wherein the source follower stage comprises an NMOS source follower.

5. The timing interpolator circuit of claim 4, wherein the second source follower stage comprises a PMOS source follower.

6. The timing interpolator circuit of claim 5, wherein the NMOS source follower comprises a first NMOS transistor having a gate configured to receive the signal input to the buffer, and a source terminal configured to output the signal to the second source follower stage.

7. The timing interpolator circuit of claim 6, wherein the NMOS source follower further comprises a second NMOS transistor configured as a load for the first NMOS transistor.

8. The timing interpolator circuit of claim 6, wherein the PMOS source follower comprises a first PMOS transistor having a gate configured to receive the signal provided from the source terminal of the first NMOS transistor and a source terminal configured to provide the signal to the input stage circuitry.

9. The timing interpolator circuit of claim 8, wherein the PMOS source follower further comprises a second PMOS transistor configured as a load for the first PMOS transistor.

10. The timing interpolator circuit of claim 5, wherein the input stage circuitry comprises a differential pair of transistors configured to receive a differential input signal.

11. The timing interpolator circuit of claim 10, wherein the differential pair of transistors comprises a third NMOS transistor having a gate terminal configured to receive the signal provided by the second source follower stage of the buffer.

12. The timing interpolator circuit of claim 11, wherein the differential pair of transistors is connected to the variable current source.

13. The timing interpolator circuit of claim 10, wherein the variable current source comprises a plurality of transistors arranged in parallel and having drain terminals, and wherein the drain terminals of the plurality of transistors are connected to the differential pair of transistors.

14. The timing interpolator circuit of claim 1, wherein the variable current source is programmable.

15. The timing interpolator circuit of claim 1, further comprising a second buffer having an input and an output, wherein the output is connected to the input stage circuitry, and wherein the second buffer comprises a first source follower stage coupled to a second source follower stage.

16. The timing interpolator circuit of claim 15, further comprising a second variable current source coupled to the input stage circuitry.

17. A ti ming circuit, comprising:
coarse delay circuitry configured to receive a clock signal and comprising a plurality of coarse delay stages configured to output a plurality of coarse delay signals of the clock signal;
a multiplexer configured to receive the plurality of coarse delay signals and to output a subset of the plurality of coarse delay signals;
fine delay circuitry configured to provide a fine delay of the subset of coarse delay signals, the fine delay circuitry comprising a control input and a programmable current source, the programmable current source adapted to provide a current at a level that varies in response to a value at the control input; and
a buffer configured to receive the subset of coarse delay signals and to output buffered signals to the fine delay circuitry.

18. The timing circuit of claim 17, wherein the buffer comprises a first source follower stage configured to receive the subset of coarse delay signals

19. The timing circuit of claim 18, wherein the buffer further comprises a second source follower stage configured to receive an output of the first source follower stage and to provide the buffered signals to the fine delay circuitry.

20. The timing circuit of claim 17, wherein the timing circuit is implemented in low voltage CMOS circuitry.

21. A method of operating a timing generator having a coarse delay stage and a fine delay stage, comprising:
programming a current source in the fine delay stage;
generating a signal in the coarse delay stage;
buffering the signal in a first stage, the buffering in the first stage shifting the voltage of the signal in a first direction;
buffering the signal in a second stage, the buffering in the second stage shifting the voltage of the signal in a second direction, opposite the first direction; and
applying the signal buffered in the second stage to an input of the fine delay stage.

22. The method of claim 21, wherein the buffering in the first stage shifts the voltage of the signal down.

23. The method of claim 21, wherein the coarse delay stage has a first output impedance and applying the signal to the input of the fine delay stage comprises driving the fine delay stage with an output impedance lower than the output impedance of the coarse delay stage.
